(19) United States
(12) Patent Application Publication
(10) Pub. No.: US 2023/0126149 A1
(43) Pub. Date: Apr. 27, 2023

(54) METHOD FOR MANUFACTURING A SILICON-BASED TIMEPIECE COMPONENT

(71) Applicant: PATEK PHILIPPE SA GENEVE, Genève (CH)

(72) Inventors: Jean-Luc BUCAILLE, Présilly (FR); Sylvain JEANNERET, Colombier (CH)

(21) Appl. No.: 17/912,007

(22) PCT Filed: Mar. 16, 2021
(86) PCT No.: PCT/IB2021/052155

§ 371 Date: Sep. 15, 2022

(30) Foreign Application Priority Data
Mar. 19, 2020 (EP) 20164297.2

(51) Int. Cl. G04B 31/06; G03F 7/20; G03F 7/075; G03F 1/80; G04B 17/04; G04B 17/22; G04B 17/32; G04B 19/04; G04B 19/06; G04D 3/00

(52) U.S. Cl. CPC G04B 31/06; G03F 7/202; G03F 7/0755; G03F 1/80; G04B 17/04; G04B 17/222; G04B 17/32; G04B 19/04; G04B 19/06; G04D 3/0069

(57) ABSTRACT

Disclosed is a method for manufacturing a horological component according to which a silicon-based piece having the desired shape of the horological component is produced and the piece is subjected to a thermal oxidation and deoxidation treatment to remove a predetermined thickness of silicon in order to increase the mechanical strength of the piece. This method is characterized in that the thermal oxidation and deoxidation treatment is carried out in several steps, each step including a thermal oxidation phase followed by a deoxidation phase.

### CROSS-REFERENCE TO RELATED APPLICATIONS

This application is the U.S. national phase of International Application No. PCT/IB2021/052155 filed Mar. 16, 2021 which designated the U.S. and claims priority to EP Patent Application No. 20164297.2 filed Mar. 19, 2020, the entire contents of each of which are hereby incorporated by reference.

### BACKGROUND OF THE INVENTION

### Field of the Invention

The present invention relates to a method for manufacturing a silicon-based horological component, in particular for a wristwatch or a pocket watch.

### Description of the Related Art

Silicon is a material highly valued in mechanical watchmaking for its advantageous properties, in particular its low density, its high resistance to corrosion, its non-magnetic character and its ability to be machined by micro-fabrication techniques. It is thus used to manufacture hairsprings, balances, oscillators with flexible guidance, escape anchors and escape wheels.

Silicon nevertheless has the disadvantage of low mechanical strength, a disadvantage which is aggravated by the etching method generally used for its machining, i.e. the deep reactive ion etching known as DRIE, which leaves sharp edges and creates flatness defects in the shape of ripples (called “scalloping”) on the sides of the piece. This low mechanical strength is problematic for the manipulation of the components during their assembling in a movement or in the event of shocks undergone by the watch. The components can indeed easily break. To address this problem, silicon horological components are generally reinforced by a silicon oxide coating having a thickness much greater than that of the native oxide, as described in patent application WO 2007/000271. This coating is generally left on the final component but, according to the teaching of patent application EP 2277822, it can be removed without significantly affecting the mechanical strength.

In the case of springs, the mechanical strength must also be sufficient for the component to be able to deform elastically without breaking during its operation to perform its function. For a hairspring intended to equip a balance or for the flexible guiding member of an oscillator without pivots, the stresses in operation are relatively low, of the order of a few hundred MPa at most, so that the mechanical strength provided by the silicon oxide layer may in theory be sufficient. However, given the oscillation frequencies in operation (4 Hz, 10 Hz or even 50 Hz), the number of cycles is high, which can lead to risks of fatigue failure. For other springs such as mainsprings, in particular barrel springs, or certain hammer or rocker springs, the stresses undergone during their operation are much higher, of the order of a few GPa, and require the choice of manufacturing materials of high elastic limit such as steels, nickel-phosphorus alloys, Nivaflex® (an alloy based on Co, Ni, Cr and Fe having an elastic limit of about 3.7 GPa), metallic glasses (cf. patents CH 698962 and CH 704391) or metal/diamond or metalloid/diamond composite materials (cf. patent CH 706020 of the applicant).

Since the applicant's patent application WO 2019/202378, it is possible to produce silicon horological springs capable of withstanding particularly high stresses and also having high fatigue strength. The method described in this patent application comprises a succession of steps which considerably improves the quality of silicon springs, in particular the surface condition and the roundness of the edges, which results in an average breaking stress close to 5 GPa. According to this method, the springs are successively thermally oxidized, deoxidized, subjected to an annealing operation in a reducing atmosphere and covered with a silicon oxide layer; alternatively, the annealing operation can be carried out before the thermal oxidation. However, this method has drawbacks: the annealing step is expensive to implement and requires the use of a bulky machine.

### SUMMARY OF THE INVENTION

The present invention aims to remedy these drawbacks and more generally to allow the manufacture, at moderate cost, of a spring or other horological component having a high mechanical strength.

To this end, a method for manufacturing a horological component is proposed, according to which a silicon-based piece having the desired shape of the horological component is produced and the piece is subjected to a thermal oxidation and deoxidation treatment to remove a predetermined thickness of silicon in order to increase the mechanical strength of the piece, characterized in that said treatment is carried out in several steps, each step comprising a thermal oxidation phase followed by a deoxidation phase.

When a silicon piece is thermally oxidized, the silicon oxide layer that appears on its surface is formed by consuming silicon over a depth corresponding to 44% of its thickness. Therefore, after eliminating the silicon oxide layer, there remains a silicon piece of reduced size, whose surface defects (ripples, cracks, breaches, etc.) constituting incipient fractures have been reduced or even eliminated.

This effect is known in the prior art and has been described for example in patent application EP 2277822 mentioned above. However, the applicant has surprisingly found that if the oxidation-deoxidation sequence is carried out in several stages, each time with a thermal oxidation phase followed by a deoxidation phase, the mechanical strength of the component is very significantly improved.

It is certainly known in the prior art to implement an oxidation-deoxidation sequence several times (cf. EP 3181938, WO 2019/166922, WO 2019/180596, EP 3416001) but the corresponding methods are always intended to adjust the stiffness of a hairspring or the frequency of an oscillator and the repetition of the oxidation-deoxidation sequence is never intended to increase the mechanical strength. Moreover, in these methods, the oxidations and deoxidations do not make it possible to remove a predetermined thickness of silicon. Indeed, each new implementation of the oxidation-deoxidation sequence is preceded by a stiffness or frequency measurement step on which depends the thickness of silicon to be removed during said sequence. The total thickness of silicon to be removed cannot therefore be determined in advance, unlike the present invention where this thickness is not linked to any measurement of stiffness or frequency of the horological component.

When the horological component is a hairspring or an oscillator with a flexible pivot, the thermal oxidation and deoxidation treatment of the method according to the invention can be followed by steps aimed at adjusting the stiffness or the frequency of the component by one or more oxidation-deoxidation sequences each preceded by a step of measurement of the stiffness or the frequency and a step of calculation of the thickness of silicon to be removed, as described for example in the documents EP 3181938 and EP 3416001.

The adjustment of the stiffness or the frequency can alternatively be carried out before the thermal oxidation and deoxidation treatment according to the invention. Given the predetermined thickness of silicon removed by the thermal oxidation and deoxidation treatment according to the invention, one indeed knows at what stiffness or frequency the component must be adjusted to obtain a desired stiffness or frequency after the treatment.

It is also possible to complete the method according to the invention by forming a final layer on the piece, for example a silicon oxide layer, a layer improving the tribological properties, a layer forming a barrier against oxygen or a layer used to contain possible debris, even if, as regards the silicon oxide layer, the latter is rendered superfluous by the repetition of the thermal oxidation and deoxidation phases, as will be demonstrated in the following.

### BRIEF DESCRIPTION OF THE DRAWINGS

Other characteristics and advantages of the present invention will appear on reading the following detailed description given with reference to the appended drawings in which:

FIG. 1 is a diagram showing the different steps of a manufacturing method according to a particular embodiment of the invention;

FIGS. 2 and 3 are graphs showing by boxplots apparent breaking stress values obtained for several different batches of pieces.

### DESCRIPTION OF THE PREFERRED EMBODIMENTS

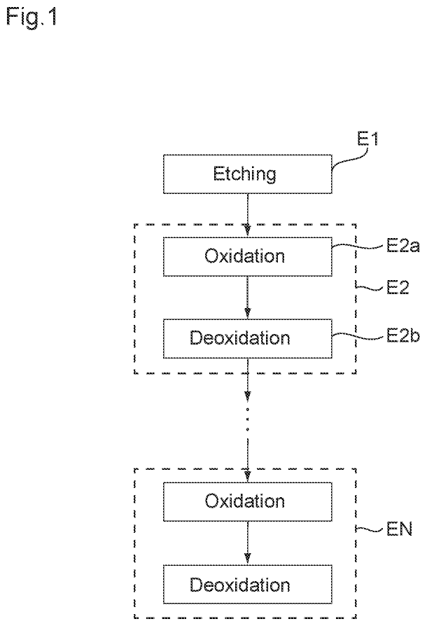

Referring to FIG. 1, a particular embodiment of the method for manufacturing a silicon-based horological component according to the invention comprises steps E1 to EN.

A first step E1 consists in etching in a silicon wafer, preferably by deep reactive ion etching (DRIE), a piece having the desired shape of the horological component.

The silicon can be monocrystalline, polycrystalline or amorphous. For isotropy of all physical characteristics, polycrystalline silicon may be preferred. The silicon used in the invention can also be doped or not. Instead of the silicon itself, the piece can be produced in a composite material comprising thick silicon layers separated by one or more thin intermediate silicon oxide layers, by etching in a silicon-on-insulator substrate (SOI substrate).

A second step E2 of the method is divided into two phases. In a first phase E2a, the piece is thermally oxidized, typically at a temperature between 600° C. and 1300° C., preferably between 900° C. and 1200° C., more preferably between 950° C. and 1150° C., in an oxidizing atmosphere comprising, for example, dioxygen gas or water vapor. This oxidation is carried out until a silicon oxide (SiO₂) layer of predetermined thickness, typically between 0.5 μm and 2 μm and preferably equal to about 1 μm, is obtained on the surface of the piece. This silicon oxide layer is formed by growth by consuming silicon, which causes the interface between the silicon and the silicon oxide to recede and reduces the surface defects of the silicon. In a second phase E2b of step E2, the piece is deoxidized, in other words the silicon oxide layer is eliminated, by example by wet etching, vapor phase etching or dry etching, preferably by wet etching with hydrofluoric acid.

The second step E2 is then repeated at least once, with parameters which may be constant or which may vary from one oxidation-deoxidation sequence to another. Preferably, however, the thickness of silicon oxide formed at each oxidation is the same. At the end of the last oxidation-deoxidation step, EN, a total thickness of silicon has been removed from the piece, the value of which is determined by the physical properties of silicon and silicon oxide and the parameters of the thermal treatment. Knowing these properties and parameters makes it possible to calculate the dimensions of the piece to be etched in step E1 to obtain the desired dimensions at the end of step EN.

Typically, said piece is part of a batch of identical pieces produced simultaneously in the same silicon wafer. After step EN, the piece and the other pieces of the batch are detached from the wafer.

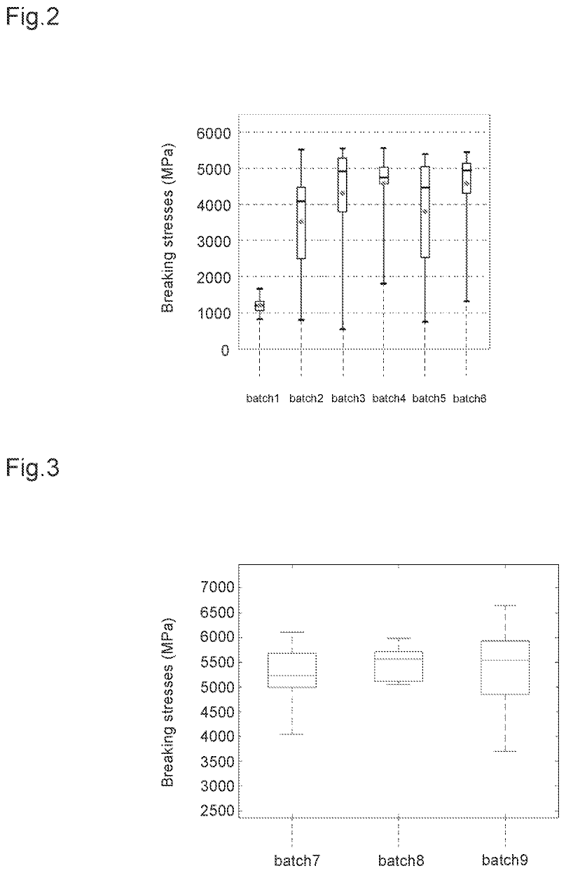

FIG. 2 shows the remarkable results obtained with the method according to the invention. By way of comparison, FIG. 2 shows the apparent breaking stress measured on identical three-point bending specimens divided into six different batches:
Batch 1: specimens manufactured only by DRIE (step E1 only). This batch is the reference batch.
Batch 2: specimens manufactured by DRIE and having undergone a thermal oxidation which coated them with a silicon oxide layer having a thickness of 1 μm followed by a deoxidation which eliminated this oxide layer (steps E1 and E2 only).
Batch 3: specimens manufactured by DRIE and having undergone a thermal oxidation which coated them with a silicon oxide layer having a thickness of 2 μm followed by a deoxidation which eliminated this oxide layer (steps E1 and E2 only).
Batch 4: specimens manufactured according to the method according to the invention (steps E1, E2 and E3), with two oxidation-deoxidation steps, the oxidation in each of these steps having led to the formation of a silicon oxide layer having a thickness of 1 μm.
Batch 5: specimens manufactured by DRIE and having undergone a thermal oxidation which coated them with a silicon oxide layer having a thickness of 3 μm followed by a deoxidation which eliminated this oxide layer (steps E1 and E2 only).
Batch 6: specimens manufactured according to the method according to the invention (steps E1 to E4), with three oxidation-deoxidation steps, the oxidation in each of these steps having led to the formation of a silicon oxide layer having a thickness of 1 μm.

All these specimens are manufactured from the same silicon wafer.

In the graph of FIG. 2, the rectangular boxes represent 50% of the pieces and the two segments on either side of each box each represent 25% of the pieces. The horizontal line inside each box represents the median value. The dot represents the mean value.

It is interesting to note that the mean value as well as the lower end of the box, which corresponds to the value of the minimum apparent breaking stress for a population comprising 75% of the pieces, are much higher for batches 4 and 6 manufactured according to the invention than for batches 3 and 5 respectively. The invention therefore demonstrates that for the same thickness of silicon removed, it is preferable to carry out the oxidation-deoxidation in several stages even if this involves the implementation of several deoxidation operations, the advantage obtained in terms of mechanical strength largely outweighing this drawback.

Steps E3 to EN, that is to say the repetition of step E2, advantageously replace the steps of annealing and formation of a final silicon oxide layer of the method described in patent application WO 2019/202378 and therefore greatly simplify the manufacture of the horological component. The method according to the invention can be supplemented by a step consisting in coating the horological component with a final silicon oxide layer, but the gain in mechanical strength provided by such a layer is quite limited or even non-existent compared to the disadvantage presented by the implementation of an additional oxidation step. This is illustrated by the graph of FIG. 3 on which it can be seen that three-point bending specimens produced by DRIE and having undergone two oxidation-deoxidation sequences with the formation of a 1 μm thickness of oxide at each oxidation (batch 7) have statistically a mechanical strength close to that of specimens obtained and treated in the same way, and obtained from the same silicon wafer, but in addition covered with a 1 μm final layer of thermal oxide (batch 8) or a 3 μm final layer of thermal oxide (batch 9).

Consequently, instead of coating the horological component with a final silicon oxide layer, the final component can be allowed to naturally cover itself with a thin layer of native oxide. As a variant, it is possible to form on the horological component a layer of a material having good tribological properties, for example carbon crystallized in the form of diamond (DLC) or carbon nanotubes, a layer forming a barrier against oxygen or a layer, for example of parylene, serving to contain the debris in the event of the component breaking.

The invention is of particular interest for horological components that are elastic or have elastic parts and that must withstand high deformation stresses during their operation or assembling, such as mainsprings (in particular barrel springs), certain return springs (in particular springs for hammers, for levers, for rockers, pawl springs or jumper springs), horological components with flexible guidance (in particular oscillators, levers or rockers) or horological components (in particular wheels, collets, anchors or impulse pins) comprising elastic parts serving to mount these components on support members such as axles. Another advantageous application are horological springs, the number of operating cycles of which is high and which are therefore subject to fatigue failure, such as hairsprings and the blades of oscillators with flexible guidance. But the invention also applies to rigid horological components liable to undergo shocks during their operation, their handling or their assembling, in particular to balances, levers, rockers, anchors, hammers, rakes, fingers, wheels, collets, axles, impulse pins, frame elements (particularly bridges), dials or indicator hands.

1. Method for manufacturing a horological component according to which a silicon-based piece having the desired shape of the horological component is produced and the piece is subjected to a thermal oxidation and deoxidation treatment to remove a predetermined thickness of silicon in order to increase the mechanical strength of the piece, wherein said treatment is carried out in several steps, each step comprising a thermal oxidation phase followed by a deoxidation phase.

2. Method according to claim 1, wherein the operation of producing the piece comprises an operation of etching a silicon-based wafer.

3. Method according to claim 2, wherein the etching is a deep reactive ion etching.

4. Method according to claim 1, wherein each thermal oxidation phase is carried out at a temperature comprised between 600° C. and 1300° C.

5. Method according to claim 1, wherein each deoxidation phase comprises an etching operation, for example a wet etching, vapor phase etching or dry etching operation.

6. Method according to claim 1, wherein each thermal oxidation phase leads to the formation of a silicon oxide layer having a thickness comprised between 0.5 and 2 μm.

7. Method according to claim 1, wherein the thermal oxidation and deoxidation treatment is not followed by a step of forming a final layer of silicon oxide.

8. Method according to claim 1, wherein the horological component is elastic or comprises at least one elastic part.

9. Method according to claim 1, wherein the horological component is a mainspring, a hammer spring, a lever spring, a rocker spring, a rake spring, a pawl spring, a jumper spring, a hairspring, a horological component with flexible guidance or a horological component comprising one or more elastic parts serving for its mounting on a support member.

10. Method according to claim 1, wherein the horological component is a balance, a lever, a rocker, an anchor, a hammer, a rake, a finger, a wheel, a collet, an axle, an impulse pin, a frame element, a dial or an indicator hand.

11. Horological component obtained by the method according to claim 1.

12. The method of claim 4, wherein each thermal oxidation phase is carried out at a temperature comprised between 900° C. and 1200° C.

13. The method of claim 4, wherein each thermal oxidation phase is carried out at a temperature comprised between 950° C. and 1150° C.

14. The method of claim 6, wherein each thermal oxidation phase leads to the formation of a silicon oxide layer having a thickness equal to about 1 μm.

15. The method of claim 9, wherein the support member is an axle.

16. Method according to claim 2, wherein each thermal oxidation phase is carried out at a temperature comprised between 600° C. and 1300° C.

17. Method according to claim 3, wherein each thermal oxidation phase is carried out at a temperature comprised between 600° C. and 1300° C.

18. Method according to claim 2, wherein each deoxidation phase comprises an etching operation.

19. Method according to claim 3, wherein each deoxidation phase comprises an etching operation.

20. Method according to claim 4, wherein each deoxidation phase comprises an etching operation.
